(19) United States
(12) Patent Application Publication
(10) Pub. No.: US 2002/0076866 A1
(43) Pub. Date: Jun. 20, 2002

(54) Method for forming self-aligned contact

(76) Inventors: Meng-Jaw Cherng, Hsinchu Hsien (TW); Lien-Jung Hung, Taipei (TW)

Correspondence Address: J.C. PATENTS, Suite 250, 4 Venture, Irvine, CA, 92618, US

(21) Appl. No.: 09/920,390

(22) Filed: Jul. 31, 2001

Related U.S. Application Data
(63) Continuation-in-part of application No. 09/371,734, filed on Aug. 10, 1999, now abandoned.

(51) Int. Cl. H01L 21/8234; H01L 21/338

(52) U.S. Cl. 438/180; 438/238; 438/229; 438/364

(57) ABSTRACT

A method of forming a landed polysilicon plug in a self-aligned contact. A substrate having a plurality of gate electrodes thereon is provided. Before forming the self-aligned contact window, a dielectric liner layer conformal to a surface profile of the substrate and the gate electrodes is formed. An inter-layer dielectric layer is next formed over the dielectric liner layer. High etching selectivity ratio between the inter-layer dielectric layer and the dielectric liner layer is chosen, and thus the dielectric liner layer is used as an etching stop layer in the process of etching out the self-aligned contact window. After a polysilicon layer that fills the self-aligned contact window and covers the dielectric layer is formed, planarization is carried out to form the landed polysilicon plug having a desired thickness.

### CROSS REFERENCE TO RELATED APPLICATION

This application is a continuation-in-part of prior applications Ser. No. 09/371,734, filed Aug. 10, 1999.

### BACKGROUND OF THE INVENTION

1. Field of Invention

The present invention relates to a method for forming a self-aligned contact on a semiconductor substrate. More particularly, the present invention relates to a method for forming a landed polysilicon plug in a self-aligned contact.

2. Description of Related Art

At present, semiconductor production has advanced to the deep submicron level. Due to the large-scale miniaturization of devices, products produced by most high-resolution manufacturing equipment are closer to the permissible error limits according to specification. In some cases, the resolution of manufacturing equipment is no longer high enough to produce a particular device feature that falls within the specified error range. When this occurs, some of the products are unable to pass inspection and have to be discarded or reworked, thus increasing cost of production and decreasing product throughput.

Therefore, how to increase the process window of current semiconductor manufacturing methods is an important topic for researchers. The self-aligned contact technique is a development aiming in this direction.

FIGS. 1A through 1D are schematic, cross-sectional views showing the progression of steps for manufacturing the landed polysilicon plugs of conventional self-aligned contacts for a dynamic random access memory (DRAM).

As shown in FIG. 1A, a substrate 100 having gate electrodes 102 thereon is provided. Each gate electrode 102 has sidewall spacers 102a and a top dielectric cap layer 102b. Both the spacers 102a and the dielectric cap layer, 102b can be silicon nitride layers formed by performing conventional chemical vapor deposition (CVD) and patterning processes. A dielectric layer 104 is formed over the substrate 100 and the gate electrodes 102. The dielectric layer 104 can be a silicon oxide layer formed by performing a chemical vapor deposition (CVD) process, for example. The dielectric layer 104 is next planarized by chemical-mechanical polishing (CMP).

As shown in FIG. 1B, the dielectric layer 104 is patterned to form a self-aligned contact window 106 using photolithographic and etching techniques. During the patterning process, the high etching selectivity between the dielectric layer 104 on one hand and the spacers 102a and the dielectric cap layer 102b on the other hand is utilized. Consequently, even if the window position is slightly misaligned during exposure in the photolithographic process, the gate electrodes 102 are still protected during the etching process.

As shown in FIG. 1C, polysilicon material is deposited to form a polysilicon layer 108 that completely fills the self-aligned contact window 106 and covers a top surface of the dielectric layer 104. The polysilicon layer 108 is formed by, for example, chemical vapor deposition (CVD).

As shown in FIG. 1D, using the dielectric layer 104 as an etching stop layer, the polysilicon layer 108 above the dielectric layer 104 is removed. Hence, a landed polysilicon plug 110 is formed inside the self-aligned contact window 106. The polysilicon layer 108 above the dielectric layer 104 can be removed by performing an etching back operation such as a chemical dry etching (CDE) operation. Since subsequent processing steps are familiar to those skilled in semiconductor manufacturing, detailed description is omitted here.

In the aforementioned method, the dielectric layer is planarized before the self-aligned contact window is formed. Such planarization process leads to a great difference in thickness (the difference in thickness is roughly the height of the gate electrode) between a first vertical distance from the substrate surface to a top surface of the dielectric layer (or thickness of the dielectric layer above the substrate), and a second vertical distance from a top surface of the gate electrode to the top surface of the dielectric layer (or thickness of the dielectric layer above the gate electrode). Therefore, in the process of forming the self-aligned contact window, the spacers and the dielectric cap layers may not provide the gate electrodes with sufficient protection. As a result, a gate-to-contact short may occur, leading to a reduction of processing window.

At present, the most commonly used method of planarizing the dielectric layer is chemical-mechanical polishing (CMP). However, the top surface of the dielectric layer in a wafer after going through a CMP operation typically has a point-to-point variation of about 2000Å. This variation in surface topography is likely to exceed the processing range for most etching recipes, hence making the preparation of the etching recipe particularly difficult.

In addition, the conventional method also requires an additional etching back operation to remove part of the polysilicon layer in order to form the landed polysilicon plug. This process increases the cost of production. Moreover, the polysilicon layer has to be slightly over-etched just to ensure that no polysilicon residue remains on the top surface of the dielectric layer. However, the over-etching of the polysilicon layer may also result in the formation of a recess on a top surface of the polysilicon plug. Maximum depth of the recess can be as high as 1000Å, and hence can lead to difficulties in a subsequent patterning operation using a conventional photolithographic process.

### SUMMARY OF THE INVENTION

Accordingly, one object of the present invention is to provide an improved method for forming a self-aligned contact, which improved method is capable of polishing a dielectric layer to a higher degree of planarity so that a greater process window is obtained. Furthermore, there is no need for carrying out an additional etching back step to form a polysilicon plug, and hence the amount of recess on a top surface of the polysilicon plug is minimized.

To achieve these and other advantages and in accordance with the object of the invention, as embodied and broadly described herein, the invention provides a method for forming a self-aligned contact. A substrate having a plurality of gate electrodes thereon is provided. A dielectric liner layer conformal to a surface profile of the substrate and the gate electrodes is formed. A dielectric layer is formed over the dielectric liner layer. The dielectric layer and the dielectric liner layer are patterned to form a self-aligned contact window that exposes a top surface of the substrate between neighboring gate electrodes. A polysilicon layer is formed that completely fills the self-aligned contact window and covers the dielectric layer. A chemical-mechanical polishing is carried out to remove the portion of the polysilicon layer lying above the dielectric layer and a portion of the dielectric layer. Ultimately, the dielectric layer has a desired thickness and the self-aligned contact window has a landed polysilicon plug inside.

In this invention, a dielectric liner layer conformal to a surface profile of the substrate and the gate electrodes is formed followed by forming an inter-layer dielectric (ILD) layer. The self-aligned contact window is formed utilizing a high etching selectivity between the dielectric liner layer and the inter-layer dielectric layer. Moreover, a polysilicon layer that fills the self-aligned contact window is formed before carrying out a planarization operation so that a planarized top surface and a polysilicon plug having a desired thickness are formed at the same time.

The inter-layer dielectric layer is not planarized prior to patterning the self-aligned contact window, and so the difference in thickness between the layer of ILD layer above the substrate and above the gate electrode is reduced. In addition, there is a high etching selectivity between the inter-layer dielectric layer and the conformal liner dielectric layer. Therefore, in the process of forming the self-aligned contact window, the gate electrodes are much better protected resulting in fewer gate-to-contact shorts. Hence, processing window of the device fabrication is increased.

Furthermore, since the planarization is only performed after the formation of the self-aligned contact window, ultimate thickness of the inter-layer dielectric layer can be reduced. This has the advantage of providing a higher processing window for forming high aspect ratio (HAR) contact in the later process.

Because both the polysilicon layer and the inter-layer dielectric layer are planarized to form the polysilicon plug in the same processing step, an additional etching back operation specifically to remove the polysilicon layer is unnecessary. Hence, cost of production can be reduced. In addition, without the etching back step, the concavity of the recess on a top surface of the polysilicon plug can be greatly reduced. The concavity of the recess is reduced from about 1000Å for a conventionally produced polysilicon plug to about 100Å for one produced by the method of this invention. One further advantage is that polysilicon residue no longer remains on a top surface of the inter-layer dielectric layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic, cross-sectional views showing the progression of steps for manufacturing a landed polysilicon plug using conventional self-aligned contact technology for a dynamic random access memory; and

FIGS. 2A through 2D are schematic, cross-sectional views showing the progression of steps for manufacturing a landed polysilicon plug in a self-aligned contact according to this invention.

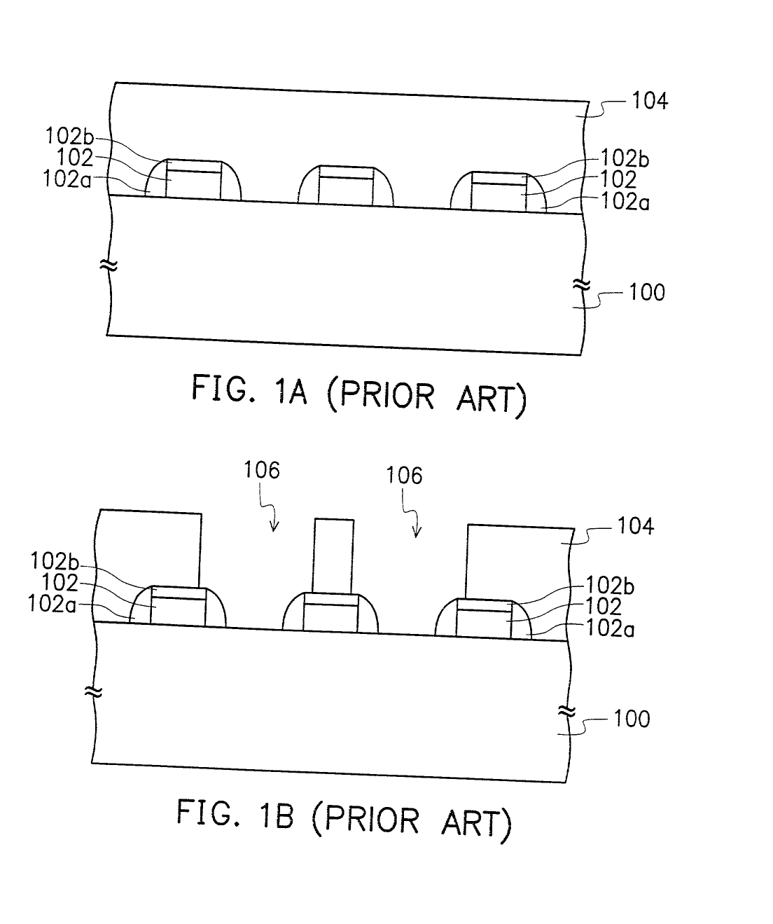

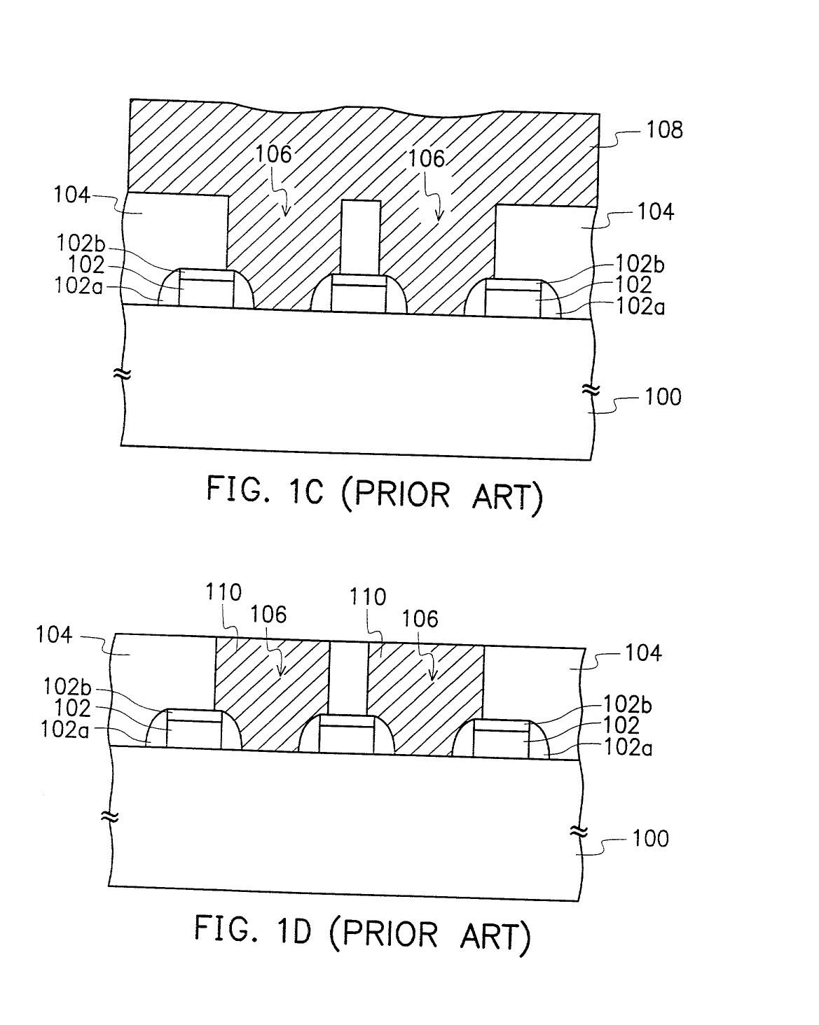

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

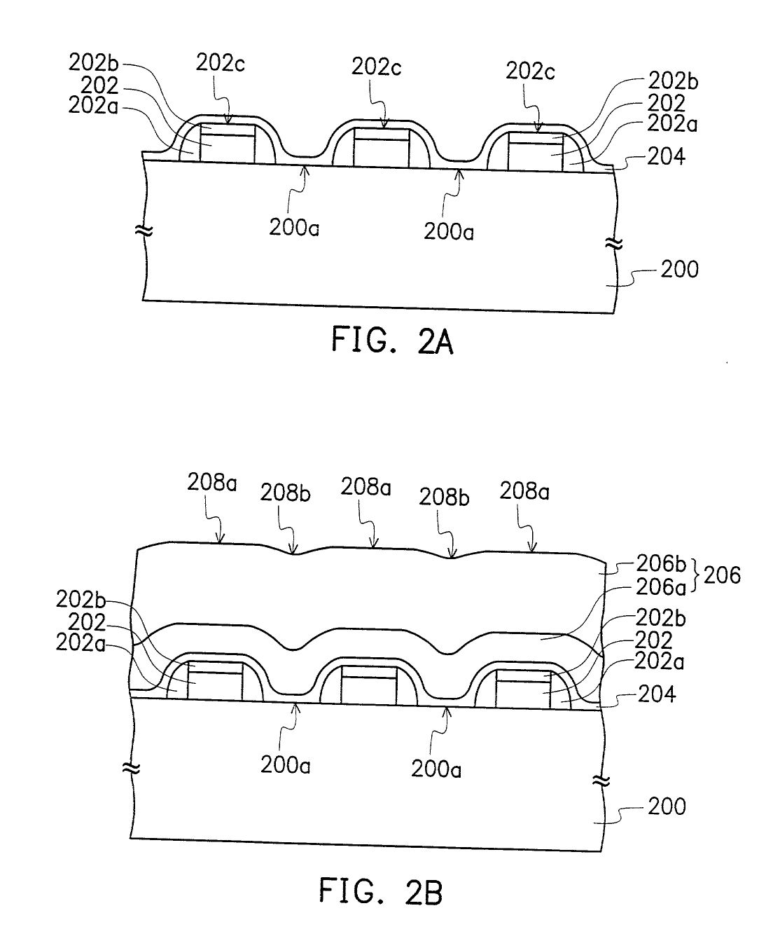

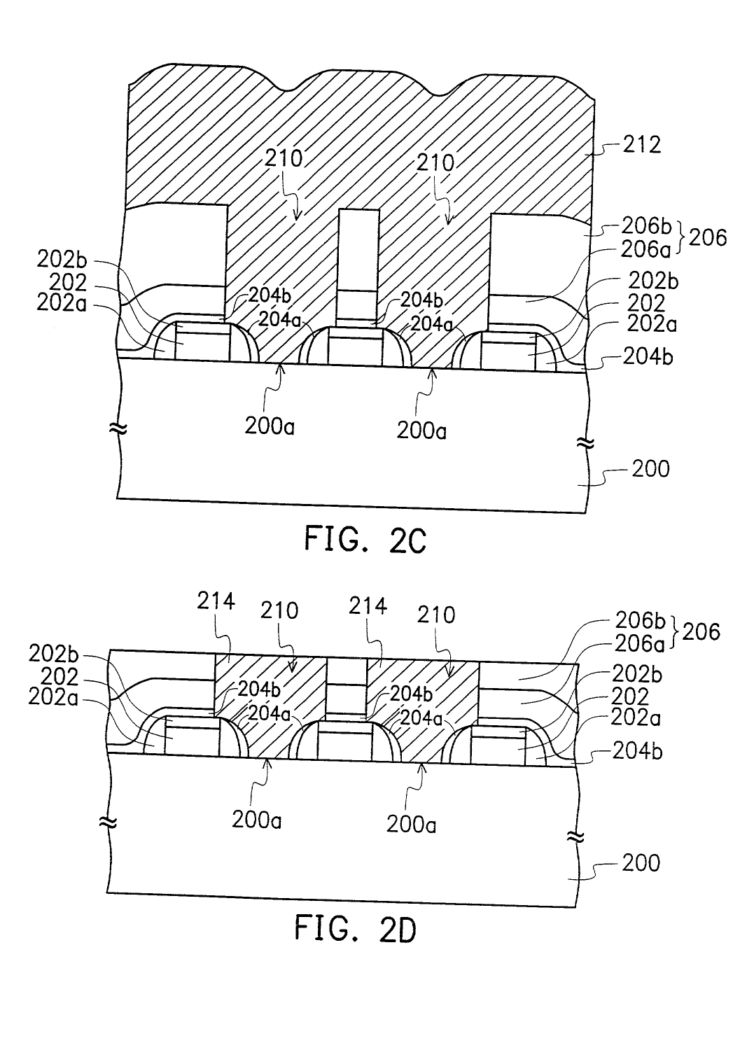

FIGS. 2A through 2D are schematic, cross-sectional views showing the progression of steps for manufacturing a landed polysilicon plug in a self-aligned contact according to this invention.

As shown in FIG. 2A, a substrate 200 having a plurality of gate electrodes 202 thereon is provided. Each gate electrode 202 has sidewall spacers 202a and a cap dielectric layer 202b on top. Both the spacers 202a and the cap dielectric layers 202b can be made using materials such as silicon oxide or silicon nitride. The gate electrode 202 and the dielectric cap layer 202b together reach a height of about 2000Å to 6000Å. In other words, height different between a substrate surface 200a and a dielectric cap surface 202c is about 2000Å to 6000Å. A dielectric liner layer 204, preferably conformal to a surface profile of the substrate 200 and the gate electrodes 202, is formed. The dielectric liner layer 204 can be a silicon nitride layer formed by, for example, chemical vapor deposition (CVD).

As shown in FIG. 2B, a dielectric layer 206 is formed over the substrate 200. In general, the dielectric layer 206 is an inter-layer dielectric (ILD) layer, for example, made up of a dielectric layer 206a that has a good gap-filling capability and a dielectric passivation layer 206b. The dielectric layer 206 can be a silicon oxide layer having a thickness of about 10000Å to 15000Å formed, for example, by chemical vapor deposition (CVD). In addition, an etching selectivity ratio between the dielectric layer 206 and the dielectric liner layer 204 is rather high.

Since the dielectric layer 206 is relatively thick, the difference in height level between surfaces 208a and 208b is only about 500Å. This small difference in height is likely to increase the processing window of a subsequent etching operation.

As shown in FIG. 2C, using photolithographic and etching techniques, the dielectric layer 206 and dielectric liner layer 204 are patterned to form a plurality of self-aligned contact windows 210. In the patterning process, the dielectric layer 206 is first etched, utilizing the high etching selectivity ratio between the dielectric layer 206, for example a silicon oxide layer, and the dielectric liner layer 204, for example a silicon nitride layer. The dielectric liner layer 204 is next etched so that the dielectric liner layer 204 is converted into a plurality of spacers 204a and dielectric passivation layers 204b. After the etching step, a surface 200a of the substrate 200 is exposed at the bottom of the self-aligned contact window between neighboring gate electrodes 202. A polysilicon layer 212 that completely fills the self-aligned contact windows 210 and covers the dielectric layer 206 is formed by, for example, chemical vapor deposition (CVD).

As shown in FIG. 2D, the polysilicon layer 212 and the dielectric layer 206 are planarized so that the portion of the polysilicon layer 212 above the dielectric layer 206 and a portion of the dielectric layer 206 are removed. Hence, the dielectric layer 206 is polished to a desired thickness and a landed polysilicon plug 214 is formed inside the self-aligned contact window 210. The planarization can be carried out, for example, by performing a chemical-mechanical polishing operation. A control mode such as a time mode is used to remove the portion of the polysilicon layer 212 above the dielectric layer 206 and a portion of the dielectric layer 206 so that the dielectric layer has a desired thickness. Since subsequent processing steps for completely forming the self-aligned contact are familiar to those skilled in semiconductor manufacturing, detailed description is omitted here.

In this invention, a dielectric liner layer conformal to a surface profile of the substrate and the gate electrodes is formed followed by forming an inter-layer dielectric layer. Formation of the self-aligned contact window utilizes a high etching selectivity between the dielectric liner layer and the inter-layer dielectric layer. Moreover, a polysilicon layer that fills the self-aligned contact window is formed before carrying out a planarization operation so that a planarized top surface and a landed polysilicon plug having a desired thickness are formed at the same time.

The inter-layer dielectric layer is not planarized prior to patterning the self-aligned contact window, and so the difference in thickness between the layer of ILD layer above the substrate and above the gate electrode is reduced. In addition, the etching selectivity ratio between the inter-layer dielectric layer and the conformal liner dielectric layer is high. Therefore, in the process of forming the self-aligned contact window, the gate electrodes are much better protected, which results in fewer gate-to-contact shorts. Hence, the processing window of the device fabrication is increased.

Furthermore, since the planarization is only performed after the formation of the self-aligned contact window, ultimate thickness of the inter-layer dielectric layer can be reduced. This has the advantage of providing a higher processing window for forming a high aspect ratio contact in the later process.

Because both the polysilicon layer and the inter-layer dielectric layer are planarized to form the polysilicon plug in the same processing step, an additional etching back operation specifically for removing the polysilicon layer is unnecessary. Hence, cost of production can be reduced. In addition, without the etching back step, the concavity of the recess on a top surface of the polysilicon plug can be greatly reduced. The concavity of recess is reduced from about 1000Å for a conventionally produced polysilicon plug to about 100Å for one produced by the method of this invention. One further advantage is that polysilicon residue no longer remains on a top surface of the inter-layer dielectric layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a contact opening in a semiconductor device comprising at least a first gate and a second gate over a substrate, wherein the said first and second gates have sidewall spacers, the method comprising the steps of:
forming a dielectric liner layer over the semiconductor device;
forming a dielectric layer over the dielectric liner layer; and
patterning the dielectric layer and the dielectric liner layer without planarizing the dielectric layer, to form a self-aligned contact window that exposes a surface of the substrate between the said first and second gates.

2. The method of claim 1, wherein the step of forming the dielectric liner layer includes depositing silicon nitride.

3. The method of claim 1, wherein the step of forming the dielectric layer includes depositing silicon oxide.

4. The method of claim 1, wherein the dielectric layer has a thickness of about 10000Å to 15000Å.

5. The method of claim 1, wherein the dielectric layer comprises a dielectric layer with a good gap-filling capability and a dielectric passivation layer.

6. A method of forming a contact plug in a semiconductor device comprising at least a first gate and a second gate over a substrate, wherein the said first and second gates have sidewall spacers, the method comprising the steps of:
forming a dielectric liner layer conformal to a surface profile of the substrate and the said first and second gates;
forming a dielectric layer over the dielectric liner layer;
patterning the dielectric layer and the dielectric liner layer without planarizing the dielectric layer, to form a self-aligned contact window that exposes a surface of the substrate between said first and second gates;
forming a polysilicon layer over the dielectric layer and filling the self-aligned contact window;
removing a portion of the polysilicon layer lying above the dielectric layer; and
removing a portion of the dielectric layer so that the contact plug is formed inside the self-aligned contact window.

7. The method of claim 6, wherein the step of forming the dielectric liner layer includes depositing silicon nitride.

8. The method of claim 6, wherein the step of forming the dielectric layer includes depositing silicon oxide.

9. The method of claim 6, wherein the dielectric layer has a thickness of about 10000Å to 15000Å.

10. The method of claim 6, wherein the dielectric layer comprises a dielectric layer with a good gap-filling capability and a dielectric passivation layer.

11. The method of claim 6, wherein the step of removing the portion of the polysilicon above the dielectric layer and the step of removing a portion of the dielectric layer includes chemical-mechanical polishing.

12. A method of forming a contact plug in a semiconductor device comprising at least a first gate and a second gate over a substrate, wherein the said first and second gates have sidewall spacers, the method comprising the steps of:
forming a silicon nitride dielectric liner layer conformal to a surface profile of the substrate and the said first and second gates;
forming a silicon oxide dielectric layer over the substrate;
patterning the silicon oxide layer and the silicon nitride layer without planarizing the silicon oxide dielectric liner layer, to form a self-aligned contact window that exposes a surface of the substrate between the said first and second gates;
forming a polysilicon layer over the dielectric layer and filling the self-aligned contact window;
performing chemical-mechanical polishing to remove a portion of the polysilicon layer lying above the silicon oxide layer and a portion of the silicon oxide layer so that the landed plug is formed inside the self-aligned contact window.

13. The method of claim 12, wherein the silicon oxide layer has a thickness of about 10000Å to 15000Å.

14. The method of claim 12, wherein the silicon oxide layer comprises a silicon oxide layer that has a good gap-filling capability and a silicon oxide passivation layer.

15. A method of forming a contact opening in a semiconductor device comprising at least a first gate and a second gate, with sidewall spacers, over a substrate, and a thin liner oxide layer disposed conformal to the surface profile of the substrate and the said first and second gates, the method comprising the steps of:
forming a dielectric layer over the semiconductor device; and
patterning the dielectric layer without planarizing the dielectric layer, to form a contact window between the said first and second gates.

16. The method of claim 15, wherein the step of forming the dielectric liner layer includes depositing silicon nitride.

17. The method of claim 15, wherein the step of forming the dielectric layer includes depositing silicon oxide.

18. The method of claim 15, wherein the dielectric layer has a thickness of about 10000Å to 15000Å.

19. The method of claim 15, wherein the dielectric layer comprises a dielectric layer with a good gap-filling capability and a dielectric passivation layer.
